(19) United States
(12) Patent Application Publication
(10) Pub. No.: US 2024/0006508 A1
(43) Pub. Date: Jan. 4, 2024

(54) SEMICONDUCTOR DEVICE INCLUDING FERROELECTRIC STRUCTURE HAVING MOIRÉ PATTERN OF TWO-DIMENSIONAL MATERIAL LAYER

(71) Applicant: SK hynix Inc, Icheon-si (KR)

(72) Inventor: Won Tae KOO, Icheon-si (KR)

(21) Appl. No.: 18/057,658

(22) Filed: Nov. 21, 2022

(30) Foreign Application Priority Data
Jul. 1, 2022 (KR) 10-2022-0081529

(51) Int. Cl. H01L 29/51; H01L 29/78

(52) U.S. Cl. CPC H01L 29/516; H01L 29/78391

(57) ABSTRACT

A semiconductor device according to an embodiment includes a substrate having a channel region, a ferroelectric structure disposed over the channel region, and a gate electrode layer disposed on the ferroelectric structure. The ferroelectric structure includes a plurality of two-dimensional material layers disposed to have a moiré pattern.

### CROSS-REFERENCE TO RELATED APPLICATIONS

The present application claims priority under 35 U.S.C. § 119(a) to Korean Application No. 10-2022-0081529, filed on Jul. 1, 2022, which is incorporated herein by reference in its entirety.

### BACKGROUND

### 1. Technical Field

The present disclosure generally relates to a semiconductor device and, more particularly, to a semiconductor device including a ferroelectric structure.

### 2. Related Art

As semiconductor chip feature size decreases, the size of a semiconductor chip unit device such as a transistor device disposed in the semiconductor chip must also decrease. Despite the decreases in the size of transistor devices, continuing efforts to develop technology for maintaining the operational reliability of the transistor devices are required.

In order to improve the operational reliability of the transistor device, research on various transistor device technologies continues, and an example of such active research involves the material applied to a gate electrode layer of the transistor device.

### SUMMARY

A semiconductor device according to an embodiment of the present disclosure may include a substrate having a channel region, a ferroelectric structure disposed over the channel region, and a gate electrode layer disposed on the ferroelectric structure. The ferroelectric structure including a plurality of two-dimensional material layers disposed to have a moiré pattern.

A semiconductor device according to another embodiment of the present disclosure may include a substrate, a channel layer disposed over the substrate and including a two-dimensional material, a ferroelectric structure disposed on the channel layer, and a gate electrode layer disposed on the ferroelectric structure. The ferroelectric structure including a plurality of two-dimensional material layers stacked to have a moiré pattern.

### BRIEF DESCRIPTION OF THE DRAWINGS

FIG. 1 is a cross-sectional view schematically illustrating a semiconductor device according to an embodiment of the present disclosure.

FIG. 2 is a graph illustrating a drain current according to a gate voltage applied to a semiconductor device according to an embodiment of the present disclosure.

FIG. 3 is a plan view schematically illustrating a ferroelectric structure of a semiconductor device according to an embodiment of the present disclosure.

FIG. 4 is a perspective view schematically illustrating a ferroelectric structure of a semiconductor device according to another embodiment of the present disclosure.

FIGS. 5A and 5B are plan views illustrating a stack form of the ferroelectric structure of FIG. 4.

FIG. 6 is a cross-sectional view schematically illustrating a semiconductor device according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

According to an embodiment of the present disclosure, a semiconductor device may include a field effect transistor. In addition, the field effect transistor may include a ferroelectric structure as a gate dielectric structure. The ferroelectric structure may include a stack structure in which two-dimensional material layers are stacked to have a moiré pattern.

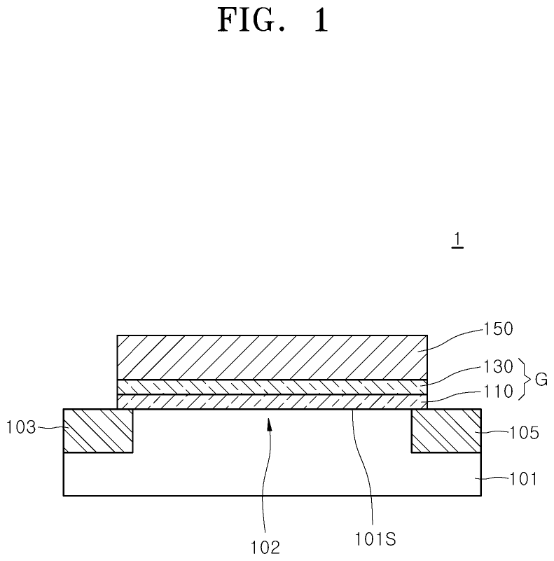

FIG. 1 is a cross-sectional view schematically illustrating a semiconductor device according to an embodiment of the present disclosure. Referring to FIG. 1, a semiconductor device 1 may include a substrate 101 including a channel region 102, a gate dielectric stack G disposed over the channel region 102, a gate electrode layer 150 disposed on the gate dielectric stack G. The gate dielectric stack G may include a base dielectric layer 110 disposed on the channel region 102, and a ferroelectric structure 130 disposed on the base dielectric layer 110. In addition, the semiconductor device 1 may further include a source region 103 and a drain region 105 that are respectively disposed at opposite sides of the channel region 102. The source region 103 and the drain region 105 may be portions of the substrate 101. In an embodiment, the semiconductor device 1 may function as a field effect transistor performing a threshold switching operation. That is, when a gate voltage equal to or higher than a threshold voltage is applied between the gate electrode layer 150 and the substrate 101, a conductive channel may be formed in the channel region 102 of the semiconductor device 1, and the semiconductor device 1 may be turned on. When an operation voltage is applied between the source region 103 and the drain region 105 in a state in which the semiconductor device 1 is turned on, electrical carriers may conduct between the source region 103 and the drain region 105 through the conductive channel. Meanwhile, when the gate voltage is removed between the gate electrode layer 150 and the substrate 101, the conductive channel in the channel region 102 may be electrically disconnected, and the semiconductor device 1 may be turned off. As described above, the semiconductor device 1 may repeatedly perform turn-on and turn-off operations according to the voltage applied to the gate electrode layer 150.

Referring to FIG. 1, the substrate 101 may include a semiconductor material. Specifically, the semiconductor material may include silicon (Si), germanium (Ge), gallium arsenide (GaAs), or the like. The substrate 101 may be doped with an n-type dopant or a p-type dopant to have predetermined conductivity. In an embodiment, the substrate 101 may be a single crystalline silicon (Si) substrate doped with an n-type dopant or a p-type dopant.

The channel region 102 may be a region in which a conductive channel is formed when a gate voltage equal to or higher than a threshold voltage is applied between the gate electrode layer 150 and the substrate 101. The conductive channel may electrically connect the source region 103 and the drain region 105 to each other.

Referring to FIG. 1, the base dielectric layer 110 may include oxide, nitride, oxynitride, or a combination of two or more thereof. The base dielectric layer 110 may have non-ferroelectric properties, compared to the ferroelectric structure 130. Specifically, the base dielectric layer 110 may exhibit paraelectricity. In an embodiment, when the substrate 101 is a silicon (Si) substrate, the base dielectric layer 110 may include silicon oxide, silicon nitride, silicon oxynitride, or a combination of two or more thereof.

Referring to FIG. 1, the ferroelectric structure 130 may include a plurality of two-dimensional material layers stacked to form a moiré pattern. Anyone of the plurality of two-dimensional material layers may form van der Waals bond with another adjacent two-dimensional material layer of the plurality of the two-dimensional material layers. For example, the ferroelectric structure 130 may have a superlattice structure of the plurality of two-dimensional material layers.

In an embodiment, each of the plurality of two-dimensional material layers may have non-ferroelectric properties. The plurality of two-dimensional material layers may be stacked to form a moiré pattern, so that the ferroelectric structure 130 may have ferroelectricity. For example, the ferroelectric structure 130 may have ferroelectric polarization generated between the plurality of two-dimensional material layers. That is, the ferroelectric polarization may be generated between one two-dimensional material layer and another two-dimensional material layer disposed to be spaced apart from the one two-dimensional material layer.

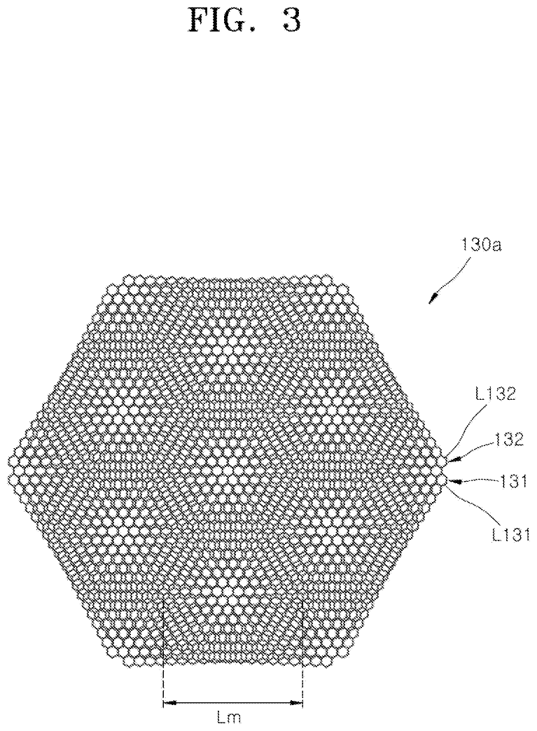

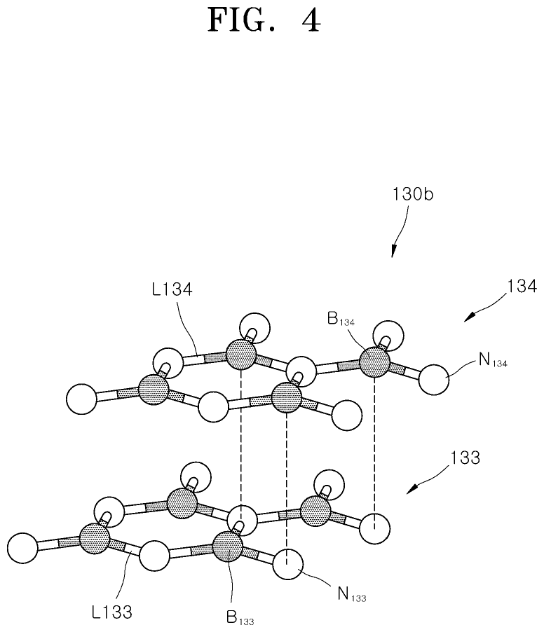

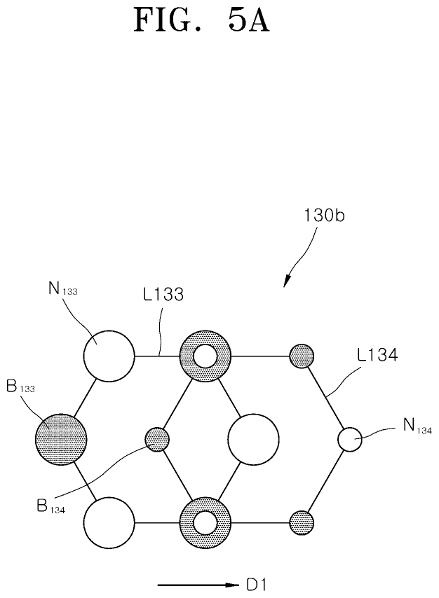

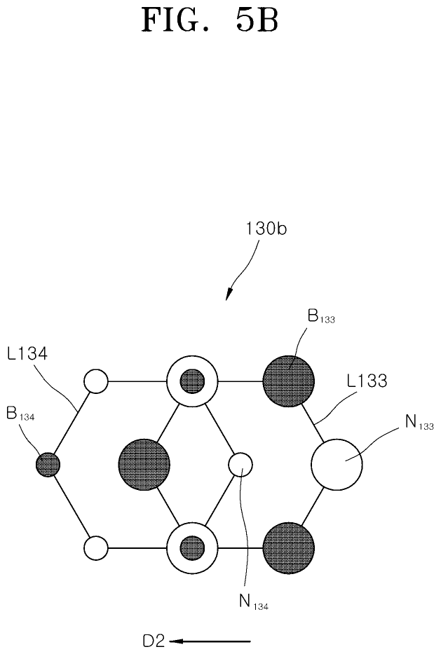

The moiré pattern may be a pattern that is formed when two layers with a periodic lattice, with lattice constants that do not match, are relatively twisted or overlapped to interfere with each other. As will be described later with reference to FIG. 3, when the moiré pattern is formed, quasi-periodic lattices having a larger scale than the lattices of the two layers may be generated. The form in which the plurality of two-dimensional material layers are stacked to form the moiré pattern may be specifically described below in embodiments related to FIGS. 4, 5A and 5B.

Each of the plurality of two-dimensional material layers may include, for example, graphene, or hexagonal boron nitride (hBN). In an embodiment, each of the plurality of two-dimensional material layers may have the same material and structure.

Meanwhile, the ferroelectric structure 130 may include the stack structure of the plurality of two-dimensional material layers. The thickness of the ferroelectric structure 130 may be controlled through the number stacked two-dimensional material layers. Accordingly, when the ferroelectric structure 130 is utilized as a gate dielectric layer of a field effect transistor, the thickness of the gate dielectric layer may be effectively controlled.

Referring to FIG. 1, the gate electrode layer 150 may include a conductive material. The conductive material may include, for example, doped semiconductor, metal, conductive metal nitride, conductive metal carbide, conductive metal silicide, or conductive metal oxide. In another example, the conductive material may include a conductive two-dimensional material. The conductive two-dimensional material may include, for example, graphene, a conductive metal-organic framework, Mxene, or the like.

As described above, the semiconductor device 1 according to an embodiment of the present disclosure may include a field effect transistor including the gate dielectric stack G disposed between the substrate 101 and the gate electrode layer 150. In the gate dielectric stack G, the base dielectric layer 110 having paraelectricity and the ferroelectric structure 130 having ferroelectricity may be connected in series to each other.

The ferroelectric structure 130 may implement a negative capacitance in a voltage range in which polarization switching occurs. In an embodiment, a subthreshold swing (SS) of the semiconductor device 1 may be reduced by using the characteristic of the ferroelectric structure 130 having a negative capacitance. Here, the subthreshold swing (SS) may correlate to the ease of turning on and turning off the current of the field effect transistor, and may be a factor in determining the switching speed of the field effect transistor.

Referring to FIG. 1 again, between the substrate 101 and the gate electrode layer 150, the capacitance C_{G} of the gate dielectric stack G may satisfy the following Equation (1) related to the capacitance Clio of the base dielectric layer 110 and the capacitance C₁₃₀ of the ferroelectric structure 130.

1/(C_{G})=1/(C₁₁₀)+1/(C₁₃₀) (1)

The subthreshold swing (SS) of the semiconductor device 1 may be generally expressed by the following Equation (2).

SS=(1+C₁₀₁/C_{G})*60 [mV/decade] (2)

Here, “decade” may correspond to an increase in a drain current (i.e., channel current) by 10 times. That is, the subthreshold swing (SS) may mean an amount of change in the gate voltage while the drain current is increased 10 times. In Equation (2), C₁₀₁ may mean a substrate capacitance contributed by the substrate 101.

In a conventional case, because the capacitance C_{G} of the gate dielectric stack G and the substrate capacitance C₁₀₁ have positive values, it may be difficult for the subthreshold swing (SS) of Equation (2) to have a value smaller than 60 mV/decade. On the other hand, according to an embodiment of the present disclosure, in Equation (1), when the capacitance C₁₃₀ of the ferroelectric structure 130 has a negative value, and at the same time, the absolute value of the capacitance C₁₃₀ of the ferroelectric structure 130 is smaller than the capacitance Clio of the base dielectric layer 110, the capacitance C_{G} of the gate dielectric stack G may have a negative value. Accordingly, in Equation (2), the subthreshold swing (SS) may have a value smaller than 60 mV/decade.

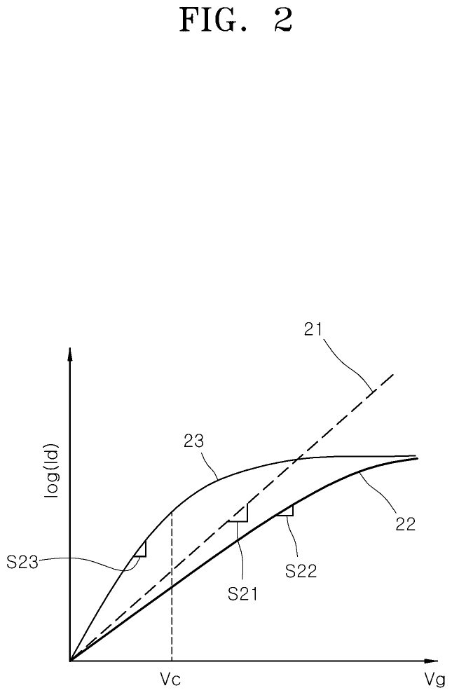

FIG. 2 is a graph illustrating a drain current according to a gate voltage applied to a semiconductor device according to an embodiment of the present disclosure. FIG. 2 illustrates a reference line 21 with a subthreshold swing (SS) of 60 mV/decade described in relation to Equation (2). In a comparative example, graph 22 in FIG. 2 illustrates the behavior of the drain current (i.e., channel current) Id of a field effect transistor in which the capacitance C_{G} of the gate dielectric stack G and the substrate capacitance C₁₀₁ have positive values. In an embodiment, graph 23 in FIG. 2 illustrates the behavior of the drain current (i.e., channel current) Id of the field effect transistor in which the capacitance C_{G} of the gate dielectric stack G implements a negative value in a state in which the substrate capacitance C₁₀₁ has a positive value.

In the comparative example graph 22, the slope S22 of a tangent line may be smaller than the slope S21 of the reference line 21 regardless of the magnitude of the gate voltage Vg. Accordingly, the subthreshold swing (SS) may be greater than 60 mV/decade. In the embodiment graph 23, under the threshold voltage Vc, the slope S23 of a tangent line may be greater than the slope S21 of the reference line 21. Accordingly, when the gate voltage Vg is less than the threshold voltage Vc, the subthreshold swing (SS) may be less than 60 mV/decade. Accordingly, in the semiconductor device 1 according to the embodiment of the present disclosure, due to the reduced subthreshold swing (SS), the on/off characteristic of the field effect transistor may be improved, and the switching speed of the field effect transistor may be improved.

FIG. 3 is a plan view schematically illustrating a ferroelectric structure of a semiconductor device according to an embodiment of the present disclosure. A ferroelectric structure 130a of FIG. 3 may be used in a ferroelectric structure 130 of a semiconductor device 1 of FIG. 1.

Referring to FIG. 3, the ferroelectric structure 130a may include two-dimensional material layers 131 and 132 disposed to form a moiré pattern. As an example, each of the two-dimensional material layers 131 and 132 may include graphene. The ferroelectric structure 130a may include superlattice structures of the two-dimensional material layers 131 and 132.

The two-dimensional material layers 131 and 132 may include a lower layer 131, and an upper layer 132 stacked on the lower layer 131. At least some of upper layer lattices L132 of the upper layer 132 may be stacked so as to be twisted at a predetermined angle with respect to lower layer lattices L131 of the corresponding lower layer 131, thereby forming the moiré pattern. The predetermined angle may be, for example, 0.5° to 1.5°. The moiré pattern may form quasi-periodic lattices Lm having a larger scale than the lower layer lattices L131 and the upper layer lattices L132, respectively. Although not necessarily limited to any one theory, when the moiré pattern is formed, ferroelectric polarization may be formed between the lower layer 131 and the upper layer 132. The orientation of the ferroelectric polarization may be switched in different directions between the lower layer 131 and the upper layer 132 by a voltage applied to both ends of the ferroelectric structure 130a. In an embodiment, the orientation of the ferroelectric polarization may be a direction substantially perpendicular to surfaces of the lower layer 131 and the upper layer 132.

The ferroelectric structure 130a of FIG. 3 may have ferroelectricity through the stack structure of the two-dimensional material layers 131 and 132 having the moiré pattern. Accordingly, by controlling the number of stacked two-dimensional material layers 131 and 132, the thickness of the ferroelectric structure 130a having ferroelectricity may be effectively controlled. As an example, compared to a conventional ferroelectric layer including metal oxide, the thickness of the ferroelectric structure 130a having ferroelectricity may be effectively reduced. As a result, according to embodiments of the present disclosure, it is possible to provide semiconductor devices in the form of field effect transistors in which the thickness of the ferroelectric gate dielectric layer can be more effectively controlled.

FIG. 4 is a perspective view schematically illustrating a ferroelectric structure of a semiconductor device according to another embodiment of the present disclosure. FIGS. 5A and 5B are plan views illustrating a stack form of the ferroelectric structure of FIG. 4.

In FIGS. 4, 5A, and 5B, a ferroelectric structure 130b may include two-dimensional material layers 133 and 134 that are stacked to form a moiré pattern. As an example, each of the two-dimensional material layers 133 and 134 may include hexagonal boron nitride.

The two-dimensional material layers 133 and 134 may include a lower layer 133 and an upper layer 134 stacked on the lower layer 133. In FIGS. 4, 5A, and 5B, B₁₃₃ and N₁₃₃ may refer to boron (B) and nitrogen (N) of the lower layer 133, respectively. B₁₃₄ and N₁₃₄ may refer to boron (B) and nitrogen (N) of the upper layer 134, respectively. In FIGS. 5A and 5B, for convenience, relatively large circles may represent boron (B) and nitrogen (N) in the lower layer 133, and relatively small circles may represent boron (B) and nitrogen (N) in the upper layer 134.

Referring to FIG. 4, at least some of upper layer lattices L134 of the upper layer 134 may be alternately arranged with lower layer lattices L133 of the corresponding lower layer 133 in a lateral direction. The lateral direction may be substantially parallel to a plane where lower layer 133 is located. As an example, as illustrated in FIG. 5A, at least some of the upper layer lattices L134 of the upper layer 134 may be arranged by sliding or translating in one direction (e.g., D1 direction), which is a lateral direction with respect to the lower layer lattices L133 of the corresponding lower layer 133. Accordingly, in FIG. 5A, in a plan view with a stacked lower layer 133 and upper layer 134, boron (B₁₃₄) of the upper layer 134 is centrally located in the lower layer lattice L133 of the lower layer 133, and nitrogen (N₁₃₃) of the lower layer 133 is located at the center of the upper layer lattice L134 of the upper layer 134. In another example, as illustrated in FIG. 5B, at least some of the upper layer lattices L134 of the upper layer 134 may be disposed by translating with respect to the lower layer lattices L133 of the corresponding lower layer 133 of FIG. 5A in a direction opposite to the D1 direction (e.g., in a D2 direction). Accordingly, the lower layer 133 and the upper layer 134 may be stacked in a state in which nitrogen (N₁₃₄) of the upper layer 134 is positioned at the center of the lower layer lattice L133 of the lower layer 133 and boron (6133) of the lower layer 133 is positioned centrally in the upper layer lattice L134 of the upper layer 134.

Through the stack method illustrated in FIGS. 4, 5A, and 5B, when the moiré pattern is formed, ferroelectric polarization may be formed between the lower layer 133 and the upper layer 134, as described above. The ferroelectric structure 130b in FIGS. 4, 5A, and 5B may have ferroelectricity through the stack of two-dimensional material layers 133 and 134 having the moiré patterns. By controlling the number of stacked two-dimensional material layers 133 and 134, the thickness of the ferroelectric structure 130b may be effectively controlled. Accordingly, it is possible to effectively reduce the thickness of the ferroelectric structure 130b, compared to a conventional ferroelectric layer including metal oxide. As a result, according to embodiments of the present disclosure, it is possible to provide a semiconductor device in the form of a field effect transistor in which the thickness of the ferroelectric gate dielectric layer may be effectively controlling.

As described above, according to embodiments of the present disclosure, there may be provided a semiconductor device in the form of a field effect transistor including a ferroelectric structure having a negative capacitance and a gate dielectric stack including a base dielectric layer having paraelectricity. In such embodiments, a semiconductor device may perform threshold switching operations. The ferroelectric structure may include a stack structure in which two-dimensional material layers are arranged to have a moiré pattern. By controlling the number of stacking of the two-dimensional material layers, the thickness of the ferroelectric structure may be effectively controlled. Accordingly, compared to conventional ferroelectric layers including metal oxide, it is possible to effectively reduce the thickness of the ferroelectric structure. According to embodiments of the present disclosure, it is possible to provide a semiconductor device in the form of a field effect transistor with controllable thickness of the ferroelectric gate dielectric layer. In addition, the ferroelectric structure may implement a negative capacitance, so that the semiconductor device in the form of a field effect transistor having excellent subthreshold swing characteristics may be provided using the ferroelectric structure.

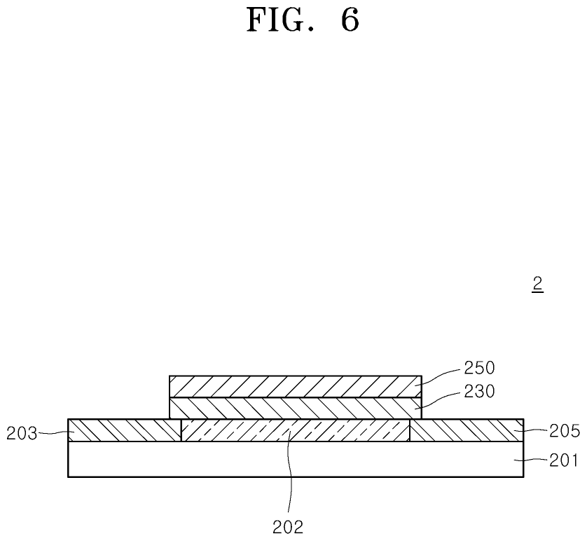

FIG. 6 is a cross-sectional view schematically illustrating a semiconductor device according to another embodiment of the present disclosure.

Referring to FIG. 6, a semiconductor device 2 may include a substrate 201, a channel layer 202 disposed on the substrate 201, a ferroelectric structure 230 disposed on the channel layer 202, and a gate electrode layer 250 disposed on the ferroelectric structure 230. In addition, the semiconductor device 2 may further include a source electrode layer 203 and a drain electrode layer 205 that are disposed at opposite sides of the channel layer 202. Compared to the semiconductor device 1 of FIG. 1, the semiconductor device 2 might not include a base dielectric layer. In an embodiment, the semiconductor device 2 may function as a memory device that stores remanent polarization in the ferroelectric structure 230 as signal information.

Referring to FIG. 6, the substrate 201 may include a semiconductor material. Specifically, the semiconductor material may include silicon (Si), germanium (Ge), gallium arsenide (GaAs), or the like. The substrate 201 may be doped with an n-type or p-type dopant to have conductivity. The electric conductivity of the substrate 201 may be smaller than the electric conductivity of the channel layer 202. In some embodiments, the substrate 201 may include an insulator. As an example, the substrate 201 may be an insulator substrate.

The channel layer 202 may be disposed on the substrate 210. The channel layer 202 may include, for example, a semiconductor material, a conductive two-dimensional material, or a conductive metal oxide material. The semiconductor material may include, for example, doped silicon (Si), doped germanium (Ge), doped gallium arsenide (GaAs), or the like. The conductive metal oxide material may include, for example, indium oxide (In₂O₃), dopant-doped indium oxide (In₂O₃), indium gallium zinc oxide (InGaZnO₄), zinc oxide (ZnO), indium gallium oxide (InGaO₃), or the like. The dopant may include titanium (Ti), tungsten (W), silicon (Si), or a combination of two or more thereof. The conductive two-dimensional material may include transition metal dichalcogenide (TMDC) or black phosphorus. The transition metal dichalcogenide may include, for example, molybdenum selenide (MoSe₂), hafnium selenide (HfSe₂), indium selenide (InSe), gallium selenide (GaSe), or the like. In an embodiment, when the channel layer 202 includes a conductive two-dimensional material, the channel layer 202 may be a stack structure of a plurality of conductive two-dimensional materials. Anyone of the plurality of the conductive two-dimensional materials may form van der Waals bond with another adjacent two-dimensional material of the plurality of the conductive two-dimensional materials.

The ferroelectric structure 230 may be disposed on the channel layer 202. The ferroelectric structure 230 may include a plurality of two-dimensional material layers stacked and arranged to form a moiré pattern. Anyone of the plurality of two-dimensional material layers may form van der Waals bond with another adjacent two-dimensional material layer of the plurality of the conductive two-dimensional material layers. The ferroelectric structure 230 may have a superlattice structure of the plurality of two-dimensional material layers. The ferroelectric structure 230 may have substantially the same configuration as the ferroelectric structure 130 described above with reference to FIG. 1.

The ferroelectric structure 230 may have remanent polarization of different orientations. The orientation of the remanent polarization may be switched by a write voltage applied between the channel layer 202 and the gate electrode layer 250. After the write voltage is removed, the switched remanent polarization may be stored in a non-volatile manner in the ferroelectric structure 230. Accordingly, the remanent polarization may function as signal information of the semiconductor device 2 that functions as a nonvolatile memory device.

The gate electrode layer 250 may be disposed on the ferroelectric structure 230. The gate electrode layer 250 may include a conductive material. The conductive material may include, for example, doped semiconductor, metal, conductive metal nitride, conductive metal carbide, conductive metal silicide, or conductive metal oxide. The conductive material may include, for another example, a conductive two-dimensional material. The conductive two-dimensional material may include, for example, graphene, a conductive metal-organic framework, Mxene, or the like.

Referring to FIG. 6 again, a source electrode layer 203 and a drain electrode layer 205 may be disposed on the substrate 201 to extend past opposite sides of the channel layer 202. Each of the source electrode layer 203 and the drain electrode layer 205 may include, for example, doped semiconductor, metal, conductive metal nitride, conductive metal carbide, conductive metal silicide, or conductive metal oxide. The conductive material may include, for another example, a conductive two-dimensional material. The conductive two-dimensional material may include, for example, graphene, conductive metal-organic framework, Mxene, or the like.

In an embodiment, each of the channel layer 202 and the ferroelectric structure 230 may include a two-dimensional material. The thicknesses of the channel layer 202 and the ferroelectric structure 230 may be determined by controlling the number of the two-dimensional material layers that are stacked in each corresponding layer. In another embodiment, each of the channel layer 202, the ferroelectric structure 230, and the gate electrode layer 250 may include a two-dimensional material. As a result, the thicknesses of the channel layer 202, the ferroelectric structure 230, and the gate electrode layer 250 may be determined by controlling the number of two-dimensional material layers stacked in each corresponding layer. In a further embodiment, each of the channel layer 202, the ferroelectric structure 230, the gate electrode layer 250, the source electrode layer 203, and the drain electrode layer 205 may include a two-dimensional material. The thicknesses of the channel layer 202, the ferroelectric structure 230, the gate electrode layer 250, the source electrode layer 203, and the drain electrode layer 205 may be controlled by the number of two-dimensional material layers stacked in each corresponding layer. In yet another embodiment, at least each of the channel layer 202 and the ferroelectric structure 230 includes a two-dimensional material so that an interfacial dielectric layer is not formed in the semiconductor device 2 due to an unintended chemical reaction between the channel layer 202 and the ferroelectric structure 230, or between the ferroelectric structure 230 and the gate electrode layer 250.

When an interfacial dielectric layer is formed by an unintended chemical reaction, the interfacial dielectric layer may have a lower dielectric constant than the ferroelectric structure 230. The interfacial dielectric layer may be electrically connected in series to the ferroelectric structure 230 between the channel layer 202 and the gate electrode layer 250. Accordingly, when a gate voltage is applied between the channel layer 202 and the gate electrode layer 250, the gate voltage may be distributed and applied to the interfacial dielectric layer having a relatively low dielectric constant. As a result, the endurance of the gate dielectric stack may be weakened according to repeated application of the gate voltage. In the semiconductor device 2 of FIG. 6, however, the interfacial dielectric layer may be excluded from the gate dielectric stack, so that the endurance of the gate dielectric stack may be improved during operation of the semiconductor device 2.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A semiconductor device comprising:
a substrate comprising a channel region;
a ferroelectric structure disposed over the channel region, the ferroelectric structure comprising a plurality of two-dimensional material layers disposed to have a moiré pattern; and
a gate electrode layer disposed on the ferroelectric structure.

2. The semiconductor device of claim 1, wherein anyone of the plurality of two-dimensional material layers form, Waals bond with another adjacent two-dimensional material layer of the plurality of the two-dimensional material layers.

3. The semiconductor device of claim 1, wherein the ferroelectric structure has ferroelectric polarization generated between the plurality of two-dimensional material layers.

4. The semiconductor device of claim 1, wherein each of the plurality of two-dimensional material layers includes one of graphene and hexagonal boron nitride (hBN).

5. The semiconductor device of claim 1, wherein the ferroelectric structure has a superlattice structure comprising the plurality of two-dimensional material layers.

6. The semiconductor device of claim 1, wherein each of the at least two of the two-dimensional material layers includes a lower layer with lower layer lattices and an upper layer with upper layer lattices, the upper layer is disposed on the lower layer, and at least some of the upper layer lattices of the upper layer are twisted at a predetermined angle with respect to the lower layer lattices of the lower layer.

7. The semiconductor device of claim 6, wherein the predetermined angle is 0.5° to 1.5°.

8. The semiconductor device of claim 1, wherein each of the plurality of two-dimensional material layers includes a lower layer with lower layer lattices, and an upper layer with upper layer lattices stacked on the lower layer, and at least some of the upper layer lattices of the upper layer are alternately disposed with the lower layer lattices of the lower layer in a lateral direction substantially parallel to a plane formed by the lower layer.

9. The semiconductor device of claim 8, wherein at least some of the upper layer lattices are arranged by sliding in the lateral direction with respect to the corresponding lower layer lattices.

10. The semiconductor device of claim 1, wherein the ferroelectric structure implements a negative capacitance.

11. The semiconductor device of claim 1, further comprising a base dielectric layer that is disposed between the channel region and the ferroelectric structure and that has non-ferroelectric properties.

12. The semiconductor device of claim 1, further comprising a source region and a drain region disposed at opposite sides of the channel region.
